(19) United States
(12) Patent Application Publication
(10) Pub. No.: US 2005/0176220 A1
(43) Pub. Date: Aug. 11, 2005

(54) Semiconductor device and method for manufacturing thereof

(76) Inventor: Kei Kanemoto, Nagano-ken (JP)

Correspondence Address: HARNESS, DICKEY & PIERCE, P.L.C., P.O. BOX 828, BLOOMFIELD HILLS, MI, 48303, US

(21) Appl. No.: 10/988,421

(22) Filed: Nov. 12, 2004

(30) Foreign Application Priority Data
Nov. 20, 2003 (JP) 2003-390683

(51) Int. Cl. C30B 1/00; H01L 21/336; H01L 29/745; H01L 21/20

(52) U.S. Cl. 438/481; 438/413; 257/213

(57) ABSTRACT

A semiconductor device for efficiently forming a raised structure at a source/drain part of an MISFET having a gate electrode formed with a metal material by low temperature processes and a method therefore are provided. In a silicon buffer film formation process, a silicon buffer film is formed within a temperature range of 500° C. to 600° C. This silicon buffer film decreases the influence of impurities on a substrate surface. In a gas mixture supply process, a silicon-and-germanium mixed crystalline film is next formed within a temperature range of 500° C. to 600° C. By forming films at a low temperature of 500° C.-600° C., a raised structure at a source/drain part of an MIS field effect transistor having a gate electrode formed with metal can be formed.

### RELATED APPLICATIONS

This application claims priority to Japanese Patent Application No. 2003-390683 filed Nov. 20, 2003 which is hereby expressly incorporated by reference herein in its entirety.

### BACKGROUND

1. Field of the Invention

The present invention relates to a method for manufacturing a transistor formed on a semiconductor substrate and, more particularly, to a method for forming a raised structure at the source/drain part of the transistor having a metal gate.

2. Related Art

Metal-insulator-semiconductor field effect transistors (hereinafter referred to as MISFETs) are shrinking in size each year due to improvement demands for more integration and performance. They are becoming smaller not only horizontally in that, for example, the gate length is becoming shorter, but also in depth in that, for example, the source/drain junction is becoming shallower and the gate insulation film is becoming thinner. As the source/drain junction becomes shallower, junction leakage caused by a silicide (a compound of silicon and metal) becomes a problem. Therefore, it is necessary to form the source/drain junction to have a sufficient depth. However, when the source/drain junction is formed to be deep, a short channel effect occurs. Thus, it is inevitable to form the lower part of the sidewall made of an insulation film to have a sufficient thickness. However, by forming the sidewall to be thick, a problem arises in which resistivity increases at the junction part below the lower part of the sidewall (hereinafter referred to as the extension region).

On the contrary, with an FD (Fully Depleted) MOSFET formed on an SOI (Silicon on Insulator) substrate, the source/drain part can reach to a BOX (Buried Oxide), and, therefore, junction leakage by using a silicide does not easily take place. However, because the silicon layer on the SOI surface is thin and the silicide readily reaches to the BOX layer, an area between the silicide and the silicon shrinks significantly, creating another problem of increasing contact resistivity.

In order to solve the above-described problems, it is effective to make the source/drain part to have a raised structure. For example, the raised structure at the source/drain part can be formed by forming a silicon single-crystalline film or a double-layered film using a silicon single-crystalline film and a single crystalline film made of silicon-and-germanium mixed crystal by vapor epitaxial growth (e.g. Japanese Unexamined Patent Publication No. 10-125605). However, there is a problem in that the silicon single-crystalline film or the single crystalline film made of silicon-and-germanium mixed crystal formed by vapor epitaxial growth tends to be influenced by impurities existing on the substrate surface. The influence is particularly noticeable with the silicon-and-germanium mixed crystal.

Further, another problem associated with the shrinkage of MISFET is depletion in a polycrystalline silicon gate. Depletion in the polycrystalline silicon gate has an influence on the transistor by decreasing the current drive. A method to solve this problem may be to form the gate electrode with metal.

As described above, with vapor epitaxial growth, the substrate surface tends to be influenced by impurities thereon. Therefore, when the impurities are found on the substrate, problems occur in which films cannot be formed by vapor epitaxial growth or the films grow as if interspersed with spots on the substrate. Publication No. 10-125605 states that the main impurities existing on the substrate are carbon. The carbon remains on the substrate surface at the time of dry etching in the transistor formation process. As a means for removing these impurities, the silicon film is formed by vapor epitaxial growth at 675-775° C. The carbon as impurities on the substrate rises over the surface of the silicon film at 675-775° C. Cl₂ gas is then supplied and the silicon film surface is etched in order to remove the impurities off the substrate. If necessary, these steps can be repeated. By removing the impurities from the substrate and by forming a silicon film or a silicon-and-germanium mixed crystalline film, a high-quality film can be formed, and thereby the desired raised structure can be formed.

Further, another problem of depletion of the gate electrode can be practically solved by forming the gate electrode with metal such as T instead of polycrystalline silicon.

However, by using metal as a material for the gate electrode, the temperature in the subsequent semiconductor formation processes needs to be lowered to 600° C. or less. With the processing temperature as low as 600° C. or less by the method according to Publication No. 10-125605, however, the substrate impurities cannot be removed, and, therefore, it is impossible to form a high-quality raised structure. Moreover, at such low temperature, a problem arises in that the velocity at which the silicon single crystalline film is formed by vapor epitaxial growth decreases dramatically. On the contrary, the silicon-and-germanium mixed crystalline film has a relatively high film formation velocity; however, the silicon-and-germanium mixed crystalline film is largely influenced by the impurities on the substrate, and, therefore, the film formation process is not stable.

The present invention aims to provide a semiconductor device for efficiently forming a raised structure at a source/drain part of an MISFET having a gate electrode formed with a metal material by low temperature processes and a method therefore.

### SUMMARY

In order to solve the above-described problems, the present invention provides a semiconductor substrate having an element isolation region and an MIS field effect transistor formation region, wherein the MIS field effect transistor includes a gate electrode formed with a metal film, a silicon buffer film formed at a source part and a drain part by epitaxial growth, and a silicon-and-germanium mixed crystalline film formed on the silicon buffer film by epitaxial growth.

According to this constitution, in order to have a raised structure at the source part and drain part of the MIS field effect transistor, a mixed crystalline film of silicon and germanium, used as its materials, is formed. Formation of a silicon-and-germanium mixed crystalline film tends to be readily influenced by impurities such as carbon existing on the surfaces of the source part and the drain part. On the contrary, formation of a silicon buffer film is not easily influenced by the impurities on the substrate surface. Therefore, by first forming a silicon buffer film at the source part and the drain part, the formed silicon buffer film traps the impurities on the substrate surface, thereby lessening the influence. As a result, a silicon-and-germanium mixed crystalline film can grow stably.

Further, in addition to the invention described above, the silicon buffer film has a thickness of 1 nm or more and 10 nm or less.

According to the constitution of the invention above, it is desirable that the silicon buffer film has a thickness of 1 nm or more and 10 nm or less. This is because, with the silicon buffer film having a thickness of 1 nm or more, the impurities on the substrate surface such as carbon can be trapped inside an interface between the substrate surface and the silicon buffer film or inside the silicon buffer film. This enables a stable growth of the silicon-and-germanium mixed crystalline film, since the influence of impurities on the substrate surface can be lessened. Further, the reason for having the thickness of 10 nm or less is that, if it is very thick, there is a problem in which the throughput of the film formation processes decreases since the velocity of vapor epitaxial growth of the silicon buffer film is low compared to that of the silicon-and-germanium mixed crystalline film.

Further, in addition to the invention described above, the silicon-and-germanium mixed crystalline film has a thickness of 10 nm or more to 100 nm or less.

According to the constitution of the invention above, it is desirable that the silicon-and-germanium mixed crystalline film has the thickness of 10 nm or more and 100 nm or less. This is because, if the silicon-and-germanium mixed crystalline film has the thickness of 10 nm or more to begin with, a silicide, for example, can grow stably on the film. Also, if a formed silicon-and-germanium mixed crystalline film is thicker than 100 nm, a problem of short circuiting tends to occur at the gate electrode and the electrodes of the source part and the drain part. Further, if it is thicker than necessary, other problems in the process occur, in which the film formation takes longer or the consumption of gas materials becomes larger. For this reason, it is desirable that the silicon-and-germanium mixed crystalline film has the thickness of 100 nm or less.

Furthermore, in addition to the above-described invention, the present invention may include a nickel silicide formed with the silicon-and-germanium mixed crystalline film.

According to this constitution, a composition of silicone and metal called a silicide is normally formed in order to form electrodes of the gate part, the source part, and the drain part. Silicide has a property of low electric resistivity. Silicide in general is heat-treated generally at 700° C.-800° C. in the process. However, because a nickel silicide can be formed at a temperature as low as 500° C., it can be applied to a semiconductor device having a gate electrode formed with a metal.

Further, the present invention may include a process of forming a silicon buffer film by introducing a semiconductor substrate having a gate electrode formed with a metal film, a source part, and a drain part into a vapor epitaxial growth chamber within the temperature range of 500° C. or more to 600° C. or less, and to include a process of forming a silicon-and-germanium mixed crystalline film at the temperature range of 500° C. or more to 600° C. or less.

According to this method, the silicon buffer film is first formed within the temperature range of 500° C. to 600° C. This silicon buffer film lessens the influence of impurities on the substrate surface. Then, the silicon-and-germanium mixed crystalline film is formed within the temperature range of 500° C. to 600° C. Since the silicon buffer film has been formed, there is not much influence of the impurities on the substrate surface, and therefore the mixed crystalline film can be formed stably. Moreover, by the method for forming the film at the low temperature of 500° C. to 600° C., a raised structure at the source part and the drain part can be formed in the MIS field effect transistor, having a gate electrode composed of a metal.

Also, in addition to the above-described invention, the silicon buffer film may be formed by supplying any one of the SiH₄, Si₂H₆, SiH₂Cl₂, SiHCl₃, SiCl₄, and SiF₄ gases or of organic silane gases in a vapor epitaxial growth chamber.

According to this method, in addition to the above-mentioned effect of the invention, a silicon buffer film can be formed by supplying any one of the silane gases as mentioned above, instead of feeding alternately with other gas such as, for example, chlorine gas such as halogen gas.

Further, in addition to the above-described invention, the process of forming the silicon-and-germanium mixed crystalline film includes a process of supplying a gas mixture of silane gas and GeH₄ gas in the vapor epitaxial growth chamber so as to form the silicon-and-germanium mixed crystalline film, and a process of supplying halogen gas after stopping the gas mixture of the silane gas and the GeH₄ gas.

According to this method, in addition to the above effect of the invention, by supplying the silane gas and the GeH₄ gas into the vapor epitaxial growth chamber, the silicon-and-germanium mixed crystalline film is formed. Then, by supplying the halogen gas, the selective growth of the silicon-and-germanium mixed crystalline film on the silicon buffer film can be enhanced. In other words, the halogen gas has an effect of enhancing selectivity in the formation of the silicon-and-germanium mixed crystalline film.

In addition to the above-described invention, by repeating the process of supplying the gas mixture and the process of supplying the halogen gas a plurality of times, the silicon-and-germanium mixed crystalline film is formed.

According to this method, in addition to the above effect of the invention, a selective growth can be enhanced by alternately supplying source gas and halogen gas that form the silicon-and-germanium mixed crystalline film.

Further, in addition to the above-described invention, the silicon buffer film may have a thickness range of 1 nm or more to 10 nm or less.

According to the method in the above invention, it is desirable that the silicon buffer film is formed to have the thickness of 1 nm or more and 10 nm or less. This is because, with the silicon buffer film having the thickness of 1 nm or more, the impurities on the substrate surface such as carbon can be trapped inside an interface between the substrate surface and the silicon buffer film or inside the silicon buffer film. Therefore, this enables a stable growth of the silicon-and-germanium mixed crystalline film since the influence of impurities on the substrate surface is lessened. Further, the reason for having the thickness of 10 nm or less is that, if it is very thick, there is a problem in which the throughput of the film formation process decreases, since the velocity of vapor epitaxial growth of the silicon buffer film is low compared to that of the silicon-and-germanium mixed crystalline film.

Moreover, in addition to the above-described invention, the silicon-and-germanium mixed crystalline film has the thickness range of 10 nm or more to 100 nm or less.

According to the method in the above-described invention, it is desirable that the silicon-and-germanium mixed crystalline film has the thickness of 10 nm and 100 nm or less. This is because, if the silicon-and-germanium mixed crystalline film is first formed to have the thickness of 10 nm or more, a suicide, for example, can grow stably on the film. Also, if the silicon-and-germanium mixed crystalline film is formed to have the thickness of 100 nm or more, a problem of short circuiting tends to occur at the gate electrode and the electrodes of the source part and the drain part. Further, if the silicon-and-germanium mixed crystalline film is thicker than necessary, other problems in the process occur, in which the film formation process takes longer or the consumption of gas materials becomes larger. For this reason, it is desirable that the silicon-and-germanium mixed crystalline film has the thickness of 100 nm or less.

### BRIEF DESCRIPTION OF THE DRAWINGS

FIGS. 1(a)-(c) show cross sectional views of the processes for manufacturing the semiconductor device according to the present embodiment.

FIG. 2 is a flow chart of the processes for manufacturing the semiconductor device according to the present embodiment.

FIG. 3 is an enlarged cross section of the source part (or the drain part) according to the present embodiment.

FIG. 4 is a graph showing the correlation between the source gas supply time and the film thickness of the Si film or of the SiGe-mixed crystalline film by the epitaxial growth process according to the present embodiment.

### DETAILED DESCRIPTION

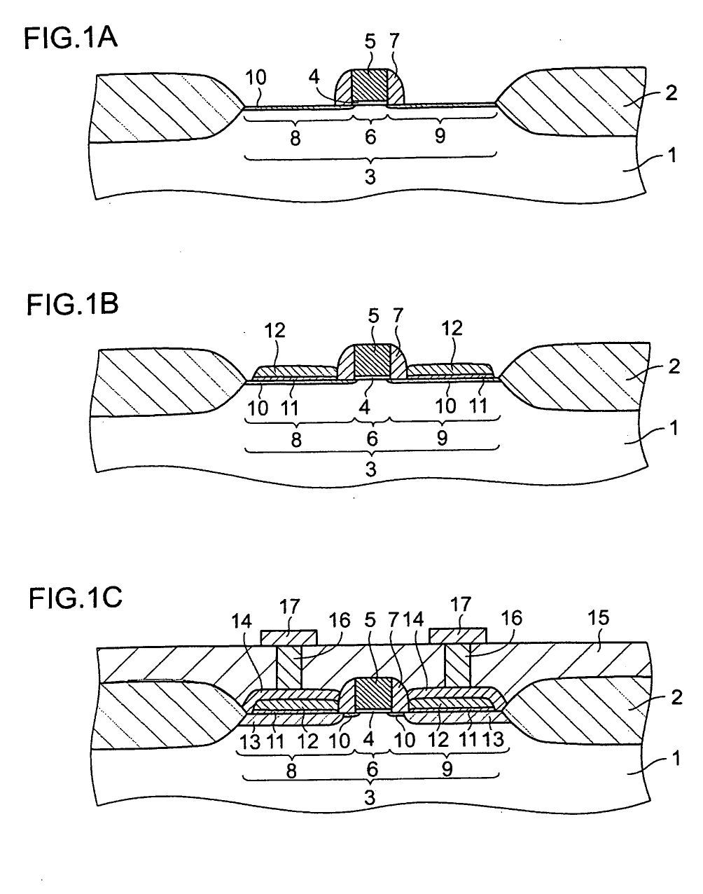

The preferred embodiments of the present invention will now be described with reference to FIG. 1 to FIG. 4.

FIG. 1 shows cross sectional views of the processes for manufacturing the MISFET of the present embodiment. First, FIG. 1(a) will be described. In the constitution of FIG. 1(a), there is a LOCOS (Local Oxidation of Silicon) 2, as an element isolation region, formed with a thick silicon oxide film on both ends of a silicon substrate 1 as a semiconductor substrate. Also, the central portion located between the LOCOS's 2 is an MIS field effect transistor formation region (a MISFET formation region) 3. At the central portion of the MISFET formation region 3, a gate part 6 composed of a gate insulation film 4 and a gate electrode 5 is formed. The gate insulation film 4 is formed with a thin silicon oxide film, and the gate electrode 5 is formed with metal in the present embodiment. Along the side of the gate part 6, a sidewall 7 is formed as an insulation film. The sidewall 7 is formed with a silicon oxide film. Between the LOCOS's 2 and the gate part 6 are a source part 8 and a drain part 9. With MISFETs, the source part 8 and the drain part 9 are identical in their compositions. Below the source part 8 or the drain part 9, an extension region 10 is formed. The extension region 10 extends towards below the sidewall 7 but not towards below the gate part 6. The extension region 10 acts as a part at which the source part 8 or the drain part 9 couples electrically with a channel.

Now, the formation process of FIG. 1(a) will be described. A silicon nitride film (not shown) is formed over the silicon substrate 1 over which a silicon oxide film has been formed. Then, after removing the silicon nitride film from the region where the element isolation region 2 will be formed, the silicon oxide film is further thermo-oxidized for growth to form a thick silicon oxide film. This thick silicon oxide film becomes the LOCOS 2. Then, the gate insulation film 4 is formed over the MISFET formation region 3. The gate insulation film 4 is a silicon oxide film and is formed by thermo-oxidation. Next formed is the gate electrode 5. Although for a normal MISFET polycrystalline silicon is used, the gate electrode 5 of the present embodiment is composed of Ta, TaN, or a lamination layer thereof, for example. The gate electrode 5 is formed by sputtering. A specified patterning using photolithography is conducted for the gate insulation film 4 and the gate electrode 5, which are then processed by dry etching to form the gate part 6.

Next, by ion implantation, the extension region 10 is formed at the source part 8 and the drain part 9. After forming the extension region 10, the sidewall 7 with the silicon nitride film is formed along the side of the gate part 6. The silicon nitride film is formed, for example, by plasma CVD. Incidentally, the sidewall 7 may be formed into a lamination composing the silicon nitride film and the silicon oxide film.

Next, FIG. 1(b) will be described. In FIG. 1(b), a single crystalline silicon buffer film 11 is formed at the source part 8 and the drain part 9, on which a single crystalline, silicon-and-germanium mixed crystal (hereinafter referred to as SiGe) film 12 is formed. Due to the double-layered structure of the single crystalline silicon buffer film 11 and the single crystalline SiGe film 12, the raised structure at the source part 8 and the drain part 9 is formed.

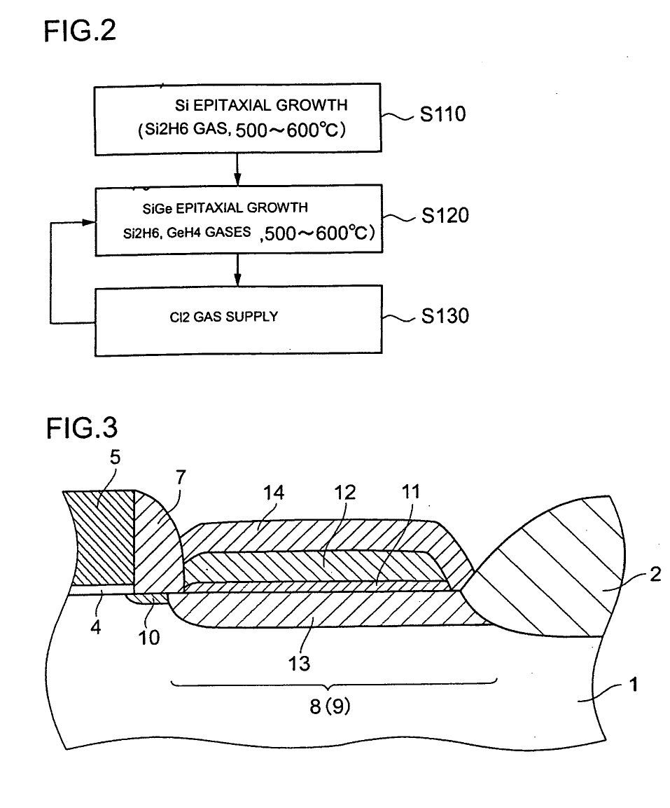

The formation method of FIG. 1(b) will now be described. First, the silicon substrate 1 that has been formed to have the structure of FIG. 1(a) is wet-etched in order to remove impurities on the silicon substrate 1 such as an organic matter or metal. The wet-etching may be repeated for a plurality of times depending on the surface condition of the silicon substrate 1, or acid-washing may be conducted using more than one kind of acid. Next, the silicon substrate 1 is placed in a vapor epitaxial growth chamber to form the silicon buffer film 11. The silicon buffer film 11 and the SiGe film 12 formed here are so-called non-doped films free from impurities. Also, a composition ratio of Ge in Si in the SiGe film 12 is in the range of 10% to 50% or, preferably, of 10% to 30%. When the composition ratio of Ge is higher, a lattice constant becomes larger, making it difficult to form the SiGe film 12 free from crystal defects. Moreover, if the composition ratio of Ge is below 10%, the formation rate or the features of the film will not be very different from those of the silicon buffer film 11, and, therefore, it will be no advantage in forming the SiGe film 12. Incidentally, the formation of these silicon buffer film 11 and the SiGe film 12 will be described in detail with reference to FIG. 2, a flow chart showing the processes in a vapor epitaxial growth chamber.

Now, FIG. 1(c) will be described. In FIG. 1(c), the SiGe film 12 formed at the source part 8 and the drain part 9 has become a nickel silicide 14 by reacting with nickel. Over the silicon substrate 1 is formed an interlayer insulation film 15. The interlayer insulation film 15 is formed with a silicon oxide film or with a silicon oxide film including either boron or phosphorus or both. On the interlayer insulation film 15, aluminum used as an electric wire 17 is formed. The aluminum used as the electric wire 17 and the nickel silicide 14 over the source part 8 and the drain part 9 are electrically coupled by a conductive layer 16, which was formed when the interlayer insulation film 15 was pierced. The conductive layer 16 is formed with tungsten or aluminum.

Now, the formation method in FIG. 1(c) is described. An ion implantation is conducted at the regions of the source part 8 and the drain part 9 of the silicon substrate 1, which have been formed up to now. By the ion implantation, an electrically coupling region (hereinafter referred to as a contact region) 13 inside the silicon substrate 1 below the source part 8 and the drain part 9. Further, since the ion implantation is also conducted to the silicon buffer film 11 and the SiGe film 12, impurities are introduced into the films, lowering the resistivity of the films.

Next, a thin nickel film is formed over the entire surface of the silicon substrate 1 by sputtering. Then, a heat treatment is carried out at a temperature around 500° C. When treated with heat, the nickel on the silicon surface or on the SiGe film 12 reacts with the silicon or the SiGe thereof, thereby forming a nickel silicide 14. On the other hand, the nickel on the silicon oxide film, that forms the element isolation region 2, or on the sidewall 7, that is formed with the metal gate electrode 5 and the silicon oxide film, does not react with the silicon oxide or the metal thereof.

Next, by wet-etching the silicon substrate 1, on which the nickel silicide 14 has been formed, the unreacted nickel is removed so that only the nickel silicide remains. The nickel silicide 14 is thus formed by self-aligning only on the source part 8 and the drain part 9.

FIG. 3 shows an enlarged cross section of the source part 8 (or the drain part 9). In FIG. 3, on the left, there are the gate insulation film 4, the gate part 6 formed with the gate electrode 5, and the sidewall 7 for protecting their side surfaces. On the right, there is the element isolation region 2 formed with the thick silicon oxide (LOCOS). The region between them is the source part 8 (or the drain part 9). In the silicon substrate 1 below the source part 8 (or the drain part 9), there are the extension region 10 and the contact region 13 formed by ion implantation. The extension region 13 acts as a part to electrically couple with the electric wire 17 (see FIG. 1(c)) formed on the interlayer insulation film 15 (see FIG. 1(c)). First, on the source part 8 (or the drain part 9) lying between the sidewall 7 and the LOCOS 2, that is, where the surface of the silicon substrate is exposed, the thin silicon buffer film 11 is selectively formed. Then, the SiGe film 12 is selectively formed thereon. On the surface of the SiGe film 12, the nickel silicide 14 is formed by self-alignment. Here, the nickel silicide 14 may be formed by reacting with a part of, or the most part of, the SiGe film. Further, even the silicon buffer film 11 may be silicidated into the nickel silicide 14. This is because, by silicidating the entire portion of the raised structure, the resistivity of the source part 8 (or the drain part 9) can be reduced.

After forming the nickel silicide 14, the silicon oxide film 15 as an interlayer insulation film is formed by PECVD (Plasma Enhanced Chemical Vapor Deposition) over the entire surface of the silicon substrate 1. At this time, it is desirable that the interlayer insulation film 15 has a high burying characteristic in order to cover elements such as the MISFET formed on the surface of the silicon substrate 1. Also, it is desirable that the film has a high flatness, since the electric wire 17 such as aluminum is formed on the film. In order to obtain these features to certain extent, BPSG (a silicon oxide introduced using boron and phosphorus) or TEOS (tetraethoxysilane) or the like is used. Further, when a high flatness is needed, CMP (Chemical Mechanical Polishing) is conducted.

Next, the conductive layer 16 will be formed. First, by photolithography, the interlayer insulation film 15 is formed by patterning so that the film 15 can be pierced on the source part 8 or the drain part. Then, by dry etching, the interlayer insulation film 15 is pierced so that the pierced part reaches down to the nickel silicide 14 on the source part 8 or the drain part 9.

Then, to be buried into the pierced part, tungsten as a conductive material is formed by PECVD. Tungsten PECVD is generally used for forming this type of a conductive layer, since tungsten has an excellent burying characteristic and a high self-flattening feature. Excessive tungsten remaining on the interlayer insulation film 15 is removed by etch-back of dry etching or by CMP. The conductive layer 16 is thus formed.

Now that the conductive layer 16 has been formed on the silicon substrate 1, aluminum used as the electric wire 17 is next formed by sputtering on the substrate 1. Then, by photolithography and dry etching, the aluminum is patterned to have a specified form, thereby forming the electric wire 17.

As thus described, the desired raised structure of the source part 8 and the drain part 9 is formed.

The following are detailed descriptions of the vapor epitaxial growth.

FIG. 2 is a flow chart showing the processes carried out in the vapor epitaxial growth chamber.

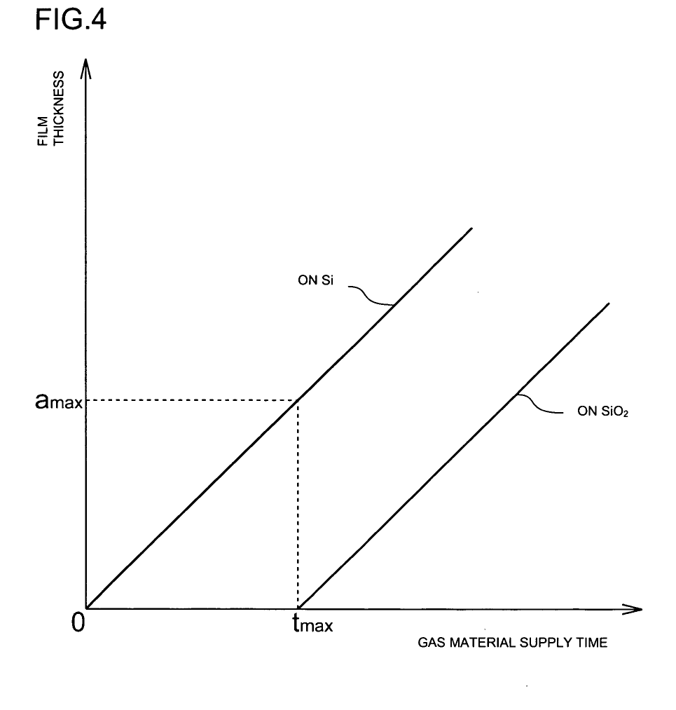

In the process for forming a silicon buffer film S110, the silicon buffer film 11 will be formed. The formation of the silicon buffer film 11 is conducted by vapor epitaxial growth within the range of 500° C. to 600° C. by supplying only a disilane (hereinafter referred to as Si₂H₆) gas. At this time, the silicon buffer film 11 is formed to have a film thickness of about 5 nm. Also, the formation of the silicon buffer film 11 is conducted by selective epitaxial growth, by which the film 11 grows only on the exposed silicon surface of the silicon substrate 1. The buffer film 11 will not be formed either on the element isolation region 2 formed with a thick silicon oxide film or on the gate electrode 5 formed with metal, nor on the sidewall 7. Here, the silicon buffer film 11 can grow even when impurities exist on the surface of the silicon substrate 1. In addition, the SiGe film 12 which will be formed later will play a role in inhibiting the impurities from influencing the silicon substrate 1. Incidentally, the selective epitaxial growth of the present embodiment will be described later in detail with reference to FIG. 4.

Here, it is desirable that the formed silicon buffer film 11 has a thickness of 1 nm or more and 10 nm or less, more preferably, of 3 nm or more and 8 nm or less, and even more preferably, of 4 nm or more and 6 nm or less. When the silicon buffer film 11 has the thickness of 1 nm or less, the impurities such as carbons existing on the substrate surface cannot be trapped inside the silicon buffer film 11, thereby negatively influencing the formation of the SiGe film 12 during the gas mixture supply process S120. Further, if the silicon buffer film 11 is formed to have the thickness of 10 nm or more, the throughput of the present process will decrease. This is because it takes time for the film to have the desired thickness, since the silicon buffer film 11 has a low formation rate.

The process for forming the mixed crystalline film of the SiGe 12 includes two processes: the gas mixture supply process S120 and the halogen gas supply process S130. In the gas mixture supply process S120, the SiGe film 12 is formed. The formation of the SiGe film 12 is conducted by the same vapor selective epitaxial growth as used to form the silicon buffer film 11. After forming the silicon buffer film 11 to have the desired thickness, Si₂H₆ gas and SiH₄ gas are supplied at a specified flow ratio within the temperature range of 500° C. to 600° C. At this time, the SiGe film 12 is formed to have a thickness of about 50 nm. Here, the SiGe film 12 grows only on the formed silicon buffer film 11, and not on the element isolation region 2, nor on the gate electrode 5, nor on the sidewall 7. Further, if tried to form the SiGe film 12 on the silicon substrate 1 without first forming the silicon buffer film 11, there will be problems that lead to unstable film formation, in that, for example, the influence of impurities on the silicon substrate 1, or the like, will prohibit formation of the SiGe film 12, the film 12 will grow isolated, and the growth rate will be low. Therefore, it is important to form the silicon buffer film 11 in the silicon buffer formation process S110 in order to stabilize the formation process of the SiGe film.

Here, it is desirable that the SiGe film 12 is formed to have a thickness of 10 nm or more and 100 nm or less, more preferably of 20 nm or more and 80 nm or less, and even more preferably of 30 nm or more and 70 or less. If the thickness of the SiGe 12 is 10 nm or thinner, a problem may occur when forming the nickel silicide 14. That is to say that, in forming the nickel silicide 14, depending on the temperature and time settings for the heat treatment, the nickel silicide 14 may reach down to the surface of the silicon substrate 1 or may grow deeper. If the nickel silicide 14 reaches to the silicon substrate 1, a problem of junction leakage will be created by the silicide. Moreover, if the SiGe film 12 has the thickness of 100 nm or more, the film 12 may go over the sidewall 7 to possibly short circuit with the gate electrode 5. Moreover, to form the film 12 having more thickness than necessary, the throughput of the process will decrease and the cost of materials will increase, and therefore is not desirable.

In the halogen gas supply process S130, chlorine gas (hereinafter referred to as Cl₂) is supplied. After stopping the supply of Si₂H₆ and GeH₄ gases, which are the material gases of the SiGe film 12, Cl₂ gas is supplied at the same temperature as used for vapor epitaxial growth.

When the supply of Cl₂ gas in the halogen gas supply process S130 is finished, the process may go back to the gas mixture supply process S120 to again supply Si₂H₆ gas and GeH₄ gas so that the SiGe film 12 can be formed again.

Further, the processes for forming the silicon buffer film 11 and the SiGe film 12 by vapor epitaxial growth in accordance with the present embodiments are conducted in the range of 500° C. to 600° C. Therefore, there is no problem even though the gate electrode is formed with metal such as Ta.

Now, the selective vapor epitaxial growth for forming the silicon buffer film 11 and the SiGe film 12 will be described.

FIG. 4 is a graph showing the relationship between the time and the film thickness when the material gases for the silicon buffer film 11 or the SiGe film 12 are supplied. The graph depicts two straight lines, the line going through the origin is the line on the silicon surface and the other line (not going through the origin) is the line on the silicon oxide surface. As can be seen in the graph of FIG. 4, on the silicon surface, the film growth starts at the same time that the source gas is supplied, while, on the silicon oxide, the film growth starts slightly after the source gas is supplied. It shows here that the film did not start growing on the silicon oxide until the time tₘₐₓ. When aₘₐₓ indicates the thickness of the film formed on the silicon up to the time tₘₐₓ, then the film is selectively formed only on the silicon up to the time tₘₐₓ and up to the thickness aₘₐₓ. Therefore, if a desired film thickness is aₘₐₓ or less, the film can be formed before the time tₘₐₓ, enabling its selective epitaxial growth. Further, the formation of the silicon buffer film 11 shows quite the same relationship as that in the formation of the SiGe film 12. However, the film formation rates (the slopes of the straight lines in the graph) of the silicon buffer film 11 and the SiGe film 12 differ, in which the formation rate of the SiGe film 12 is higher. Further, the graph of FIG. 4 indicates that the films will be self-aligned and will grow by selective epitaxial growth up to the thickness aₘₐₓ, if only desired source gases of the films are supplied.

In the present embodiment, the silicon buffer film 11 is formed in such a condition that the desired thickness a (≦aₘₐₓ) is to be obtained before the material gas supply time tₘₐₓ as shown in FIG. 4. The silicon buffer film 11 can be formed in a single process since the film to be formed is thin.

Also, with the SiGe film 12, because the film to be formed is relatively thick, the formed thickness may sometimes exceed aₘₐₓ. However, with the SiGe film 12, because the mixture supply process S120 and the halogen gas supply process S130 can be repeated as described in reference to FIG. 2, there is no problem in so far as the formed thickness does not exceed aₘₐₓ in a single process of the gas mixture supply process S120. Further, because Cl₂ gas etches the SiGe film on the LOCOS only very slightly in the halogen gas supply process S130, it is not a problem if the SiGe film 12 formed in the gas mixture supply process S120 exceeds aₘₐₓ, as long as the amount etched is within the limit of the amount to be etched by Cl₂ gas.

Additionally, in the graph, the predominant parameter of the slope, namely the film formation rate, is the temperature. That is, as the temperature becomes higher, the slope of the graph becomes sharper. This means that the rate of the film formation increases. Further, the time t₁, at which the film can grow selectively, changes depending of the flow amount or the flow ratio of a material gas. Therefore, the conditions for selective vapor epitaxial growth depend on various parameters such as the temperature and the amount of gas flow.

The effects of the present embodiments will be described as follows:

By forming the silicon buffer film 11 at the source part 8 and the drain part 9, impurities remaining on the surface of the silicon substrate 1 can be trapped. Thereafter, the SiGe film 12 having a high formation velocity can be formed stably. As a result, the MISFET having the raised structure at the source part 8 and the drain part 9 can be easily obtained.

By forming the silicon buffer film 11 to have the thickness ranging from 1 nm to 10 nm, the impurities remaining on the surface of the silicon substrate 1 can be trapped. Also, by minimizing the thickness of the silicon buffer film 11 having a low formation velocity, the decrease in the throughput of the film formation process can be restrained.

By forming the SiGe film to have the thickness ranging from 10 nm to 100 nm, the nickel silicide 14 can be stably formed, and the junction leakage at the source part 8 or the drain part 9 can be restrained. Further, by not forming the film 14 to be thicker than necessary, a short circuit with the gate part 6 can be prevented, and, moreover, an increase in the film formation time and in the material consumption can be prevented.

Because the silicon buffer film 11 and SiGe film 12 are formed by vapor epitaxial growth at the low temperature of 500° C.-600° C., the MISFET having the raised structure at the source part 8 and the drain part 9 can be easily obtained, even though the gate electrode 5 is made of metal that has poor heat resistance.

Because the nickel silicide 14 is formed at the low temperature of 500° C.-600° C., the MISFET having the raised structure at the source part 8 and the drain part 9 can be easily obtained, even though the gate electrode 5 is made of metal that has poor heat resistance.

In vapor selective epitaxial growth, the silicon buffer film 11 can be formed by conducting the process only once. This is because, when supplying the Si₂H₆ gas, the formation takes advantage of the time difference, that is to say, of the difference between the time when the film formation starts using the silicon and the time when the film formation starts using the silicon oxide on the surface of the silicon substrate 1.

By alternately supplying the material gas of the SiGe film 12 and the chlorine gas, the selective growth of the SiGe film 12 can increase. Further, even when the growth time exceeds the time for selective epitaxial growth, it is possible to remove the SiGe film 12, which has been formed on the silicon oxide film such as the LOCOS 2 or on the metal gate electrode 5, because of the etching effect exerted by the chlorine gas.

In addition, the present invention is not limited to the above-described embodiments but can be altered at least as follows:

The element isolation region 2 may be formed to have a structure by STI (Shallow Trench Isolation) instead of by LOCOS of the present embodiment. Also, when using an SOI substrate, the element isolation region 2 may be formed by a mesa isolation.

The electric wire 17 formed on the interlayer insulation film 15 may be formed with Cu instead of Al according to the present embodiment.

The material for the conductive layer 16, which is formed for electrically coupling the electric wire with the source part 8 or the drain part 9, may be Al or Cu instead of W.

The silicon buffer film 11 or the SiGe film 12 formed by vapor epitaxial growth is non-doped according to the present embodiment. However, As, P, and B, for example, may be doped at the time of the film formation.

The part at which the silicon buffer film 11 and the SiGe film 12 are grown by selective epitaxial growth is not limited to the source part 8 or the drain part 9 but may be at the channel part of the MISFET.

The gas used for forming the silicon buffer film 11 is not limited to Si₂H₆ but may be any one of SiH₄, SiH₂Cl₂, SiHCl₃, SiCl₄, and SiF₄ gases or of organic silane gases.

The gas used for forming the SiGe 12 is not limited to Si₂H₆ but may be any one of SiH₄, SiH₂Cl₂, SiHCl₃, SiCl₄, and SiF₄ gases or of organic silane gases.

The silicon buffer film 11 may be annealed before the formation.

Now, the technical concepts derived from the present embodiments along with the effects thereof will be described below.

The semiconductor device, wherein the amount of germanium contained in the above described silicon-and-germanium mixed crystalline film is 10% or more and 50% or less.

With such composition, if the composition ratio of the silicon-and-germanium mixed crystalline film is in the range of 10% to 50%, the single crystalline film of the mixed crystalline film can be stably formed.

1. A semiconductor device providing a semiconductor substrate having an element isolation region and an MIS field effect transistor formation region, the MIS field effect transistor comprising:
a gate electrode formed with a metal film;
a silicon buffer film formed on a source part and a drain part by epitaxial growth; and
a silicon-and-germanium mixed crystalline film formed by epitaxial growth on the silicon buffer film.

2. The semiconductor device according to claim 1, wherein the silicon buffer film has a thickness of 1 nm or more to 10 nm or less.

3. The semiconductor device according to claim 1, wherein the silicon-and-germanium mixed crystalline film has a thickness of 10 nm or more to 100 nm or less.

4. The semiconductor device according to claim 1, comprising a nickel silicide formed on the silicon-and-germanium mixed crystalline film.

5. A method for manufacturing a semiconductor device comprising the steps of:
forming a silicon buffer film by introducing a semiconductor substrate having a transistor provided with a gate electrode formed with a metal film, a source part, and a drain part into a vapor epitaxial growth chamber within a temperature range of 500° C. or more to 600° C. or less; and
forming a silicon-and-germanium mixed crystalline film within a temperature range of 500° C. or more to 600° C. or less.

6. The method for manufacturing the semiconductor device according to claim 5, comprising the step of forming the silicon buffer film by supplying any one of SiH₄, Si₂H₆, SiH₂Cl 2, SiHCl₃, SiCl₄, and SiF₄ gases or of organic silane gases into the vapor epitaxial growth chamber.

7. The method for manufacturing the semiconductor device according to claim 5, further comprising:
supplying a gas mixture of silane gas and GeH₄ gas in the vapor epitaxial growth chamber so as to form the silicon-and-germanium mixed crystalline film; and
supplying halogen gas after stopping the gas mixture of silane gas and GeH₄ gas.

8. The method for manufacturing the semiconductor device according to claim 7, wherein the silicon-and-germanium mixed crystalline film is formed by repeating the step of supplying the gas mixture and the step of supplying halogen gas a plurality of times.

9. The method for manufacturing the semiconductor device according to claim 5, wherein the silicon buffer film is formed to have a thickness range of 1 nm or more to 10 nm or less.

10. The method for manufacturing the semiconductor device according to claim 5, wherein the silicon-and-germanium mixed crystalline film is formed to have a thickness range of 10 nm or more to 100 nm or less.
